(19) United States
(12) Patent Application Publication
(10) Pub. No.: US 2024/0381529 A1
(43) Pub. Date: Nov. 14, 2024

(54) METHOD FOR MANUFACTURING SUBSTRATE MATERIAL FOR SEMICONDUCTOR PACKAGE, PREPREG, AND APPLICATION FOR PREPREG

(71) Applicant: Resonac Corporation, Tokyo (JP)

(72) Inventors: Shunsuke OTAKE, Tokyo (JP); Kazuyuki MITSUKURA, Tokyo (JP); Shinji SHIMAOKA, Tokyo (JP); Hiroaki FUJITA, Tokyo (JP); Masaki TAKAHASHI, Tokyo (JP)

(21) Appl. No.: 18/691,691

(22) PCT Filed: Sep. 15, 2021
(86) PCT No.: PCT/JP2021/033952

§ 371 Date: Mar. 13, 2024

(51) Int. Cl. H05K 1/03; H01L 23/14; H05K 3/46

(52) U.S. Cl. CPC H05K 1/0373; H01L 23/14; H05K 3/4644; H05K 2201/0133; H05K 2201/0209

(57) ABSTRACT

A method for manufacturing a substrate material for a semiconductor package having an insulating substrate includes forming an insulating substrate from a prepreg by a molding treatment including increasing a temperature of a laminated body including two or more laminated sheets of a prepreg while pressurizing the laminated body. The molding treatment includes increasing the temperature of the laminated body under a heating condition in which a melt viscosity of the prepreg increases to 1000×10³ Pa·s at a rate of 55×10³ Pa·s/min or greater from a time point at which a minimum melt viscosity is exhibited.

### TECHNICAL FIELD

The present disclosure relates to a method for manufacturing a substrate material for a semiconductor package having an insulating substrate, a prepreg, and an application of the prepreg for manufacturing a substrate material for a semiconductor package.

### BACKGROUND ART

In order to realize high-speed transmission and miniaturization of semiconductor devices, it is required to connect wiring boards for semiconductor packages and semiconductor chips with high density. It has been proposed that wiring boards for semiconductor packages have a structure in which different types of semiconductor chips can be connected in parallel by means of a fine wiring layer, and a structure in which semiconductor chips having fine bumps can be packaged.

### CITATION LIST

### Patent Literature

Patent Literature 1: Japanese Unexamined Patent Publication No. H11-126978
Patent Literature 2: Japanese Unexamined Patent Publication No. H8-198982

### SUMMARY OF INVENTION

### Technical Problem

Wiring boards for semiconductor packages on which semiconductor chips are mounted are often manufactured by forming wiring on an insulating substrate formed of a substrate material for a semiconductor package. A substrate material for a semiconductor package is generally manufactured by a method including heating and pressurizing a laminated body including several laminated sheets of a prepreg.

In order to increase the density, wiring boards for semiconductor packages are sometimes required to have fine wiring lines with a width of 10 μm or less. However, in a case where such fine wiring lines are formed, minute variations in the width of the wiring lines may emerge as a problem that cannot be ignored.

An aspect of the present disclosure relates to a substrate material for a semiconductor package, which allows fine wiring lines to be stably formed while suppressing variations in the line width.

### Solution to Problem

An aspect of the present disclosure relates to a method for manufacturing a substrate material for a semiconductor package having an insulating substrate, the method including performing a molding treatment that includes increasing a temperature of a laminated body including two or more laminated sheets of a prepreg while pressurizing the laminated body to form an insulating substrate from the prepreg. The prepreg includes an inorganic fiber base material and a thermosetting resin composition impregnated into the inorganic fiber base material, and a content of the thermosetting resin composition is 40% by mass or more and 80% by mass or less based on a mass of the prepreg. The molding treatment includes increasing the temperature of the laminated body under a heating condition in which a melt viscosity of the prepreg increases to 1000×10³ Pa·s at a rate of 55×10³ Pa·s/min or greater from a time point at which a minimum melt viscosity is exhibited.

Generally, the melt viscosity of a prepreg decreases with an increase in temperature, shows the minimum value (minimum melt viscosity), and then increases. The increase rate of the melt viscosity changes depending on the influence of the heating condition and the like. According to the knowledge of the inventors of the present invention, in the molding treatment for forming a substrate material, when a laminated body including a prepreg with a specific resin content is heated under the heating condition in which the rate of increase in the melt viscosity of the prepreg increases up to 1000×10³ Pa·s at a rate of 55×10³ Pa·s/min or greater from the time point at which the minimum melt viscosity is exhibited, a substrate material having extremely small variations in thickness is formed. Then, when wiring lines are formed by using a substrate material with small variations in thickness, the variations in the line width are suppressed more than before.

Another aspect of the present disclosure relates to a prepreg including an inorganic fiber base material and a thermosetting resin composition impregnated into the inorganic fiber base material. A content of the thermosetting resin composition is 40 to 80% by mass based on a mass of the prepreg. A melt viscosity of the prepreg measured at a temperature increase rate of 4° C./min increases to 1000×10³ Pa·s at a rate of 55×10³ Pa·s/min or greater from a time point at which a minimum melt viscosity is exhibited.

By using the prepreg according to one aspect of the present disclosure in the above-described method, a substrate material for a semiconductor package, which allows fine wiring lines to be stably formed while suppressing variations in the line width, can be easily manufactured.

### Advantageous Effects of Invention

According to an aspect of the present disclosure, there is provided a substrate material for a semiconductor package, which allows fine wiring lines to be stably formed while suppressing variations in the line width. Since the variations in the line width are small, fine wiring lines can be easily formed with high density. The substrate material for a semiconductor package according to an aspect of the present disclosure is also excellent from the viewpoint of reducing warpage. A wiring board formed from the substrate material for a semiconductor package according to an aspect of the present disclosure allows a semiconductor chip having fine bumps to be mounted with high reliability and satisfactory productivity.

### BRIEF DESCRIPTION OF DRAWINGS

FIG. 1 is a cross-sectional view illustrating an example of a prepreg.

FIG. 2 is a cross-sectional view illustrating an example of a method for manufacturing a substrate material for a semiconductor package.

FIG. 3 is a cross-sectional view illustrating an example of a method for manufacturing a substrate material for a semiconductor package.

### DESCRIPTION OF EMBODIMENTS

The present invention is not intended to be limited to the examples described below.

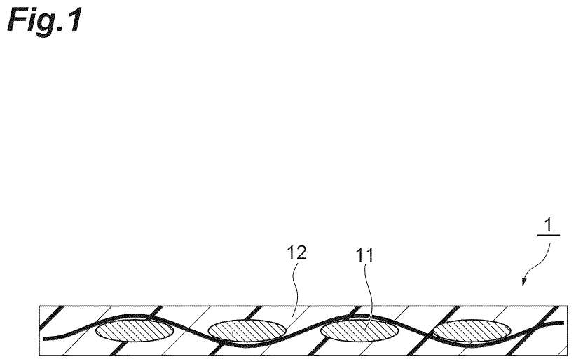

FIG. 1 is a cross-sectional view illustrating an example of a prepreg. The prepreg 1 shown in FIG. 1 includes an inorganic fiber base material 11 and a thermosetting resin composition 12 impregnated into the inorganic fiber base material 11.

The inorganic fiber base material 11 may be, for example, a woven fabric or a non-woven fabric, both of which include inorganic fibers. The inorganic fibers constituting the inorganic fiber base material 11 may be glass fibers, carbon fibers, or a combination of these. The inorganic fiber base material 11 may be a glass cloth formed from glass fibers. The proportion of glass fibers in the inorganic fibers constituting the inorganic fiber base material may be 80 to 100% by mass, 90 to 100% by mass, 95 to 100% by mass, or 99 to 100% by mass. The glass fibers may be, for example, E-glass, S-glass, or quartz glass. The thickness of the inorganic fiber base material 11 may be 0.01 to 0.20 μm.

When measured at a temperature increase rate of 4° C./min, the prepreg 1 may exhibit a melt viscosity that increases up to 1000×10³ Pa·s at a rate of 55×10³ Pa·s/min or greater from the time point at which the minimum melt viscosity is exhibited. The rate as used herein is an average value of the proportions of melt viscosity that increase per minute during the period from the time point at which the melt viscosity exhibits the minimum melt viscosity until the melt viscosity increases up to 1000×10³ Pa·s, and in the present specification, the rate may be referred to as “melt viscosity increase rate”. In a case where the time taken for the melt viscosity increases up to 1000×10³ Pa·s from the time point at which the melt viscosity exhibits the minimum melt viscosity [Pa·s] is designated as T minutes, the melt viscosity increase rate is calculated by the following formula.

$$Melt viscosity increase rate [ Pa \cdot s / min ] = ( 1000 \times 1 {0}^{3} - minimum melt viscosity ) / T$$

From the viewpoint of further suppressing the variations in the line width, the melt viscosity increase rate may be 60×10³ Pa·s/min or greater, 65×10³ Pa·s/min or greater, 70×10³ Pa·s/min or greater, 75×10³ Pa·s/min or greater, 80×10³ Pa·s/min or greater, 85×10³ Pa·s/min or greater, 90×10³ Pa·s/min or greater, 95×10³ Pa·s/min or greater, 100×10³ Pa·s/min or greater, 105×10³ Pa·s/min or greater, or 110×10³ Pa·s/min or greater, and may be 200×10³ Pa·s/min or less, 190×10³ Pa·s/min or less, 180×10³ Pa·s/min or less, 170×10³ Pa·s/min or less, or 160×10³ Pa·s/min or less.

The melt viscosity of a prepreg is the value of complex viscosity measured by a method of sandwiching a test piece of the prepreg between two sheets of parallel plates having a diameter of 8 mm, and measuring the dynamic viscoelasticity in a shear mode at a frequency of 10 Hz while increasing the temperature from 20° C. to a temperature of 200° C. or higher at a predetermined temperature increase rate (for example, 4° C./min). The thickness of the test piece for measurement is 10 to 400 μm, and if necessary, the test piece is produced by laminating two or more sheets of a prepreg. For the measurement, for example, an ARES (manufactured by Rheometric Scientific Far East Ltd.), which is a viscoelasticity measuring apparatus, can be used.

From the viewpoint of further suppressing variations in the line width, the minimum melt viscosity of the prepreg 1 measured at a temperature increase rate of 4° C./min may be 10×10³ Pa·s or less, 9.0×10³ Pa·s or less, 8.0×10³ Pa·s or less, 7.0×10³ Pa·s or less, 6.0×10³ Pa·s or less, 5.0×10³ Pa·s or less, or 4.0×10³ Pa·s or less, or may be 1.0×10³ Pa·s or greater.

The temperature at which the prepreg 1 exhibits the minimum melt viscosity may be 80° C. or higher from the viewpoint of handleability of the prepreg, or may be 120° C. or higher from the viewpoint of storage stability. The temperature at which the prepreg 1 exhibits the minimum melt viscosity may be 200° C. or lower from the viewpoint of productivity, or may be 180° C. or lower from the viewpoint of reducing warpage.

The content of the thermosetting resin composition 12 in the prepreg 1 may be 40 to 80% by mass. When using a prepreg including the thermosetting resin composition 12 at a proportion of 40 to 80% by mass, a substrate material for a semiconductor package with small variations in the thickness can be easily manufactured. The content of the thermosetting resin composition 12 can be adjusted by, for example, the amount of application of the thermosetting resin composition in accordance with the thickness of the inorganic fiber base material 11.

The content of the thermosetting resin composition 12 in the prepreg 1 can be determined by, for example, a method including partitioning a cross-sectional photograph of the prepreg 1 into a region of the inorganic fiber base material 11 and a region of the thermosetting resin composition 12 by a binarization treatment, and calculating the area of each region. In that case, it may be assumed that the density of the inorganic fiber base material 11 and the density of the thermosetting resin composition 12 are the same.

The thermosetting resin composition 12 may include an inorganic component in addition to a thermosetting resin component. The proportion of the resin component in the thermosetting resin composition 12 may be 20 to 100% by mass with respect to the mass of the thermosetting resin composition 12, may be 20 to 80% by mass from the viewpoint of reducing the linear expansion coefficient, may be 30 to 100% by mass from the viewpoint of reducing voids after lamination, or may be 40 to 100% by mass from the viewpoint of even further improving the flatness of the substrate material. From the above, the proportion of the resin component in the thermosetting resin composition 12 may be 40 to 80% by mass with respect to the mass of the thermosetting resin composition 12. That is, the proportion of the resin component in the prepreg 1 may be 16 to 64% by mass.

The proportion of the resin component included in the thermosetting resin composition 12 can be calculated by a method such as ash content measurement. Ash content measurement is a method of calculating the proportion of a resin component by carbonizing the resin component at a high temperature.

With regard to the thermosetting resin composition 12, components excluding an inorganic component may be regarded as the resin component. Examples of the inorganic component include an inorganic filler. With regard to the thermosetting resin composition 12, components excluding an inorganic filler may be regarded as the resin component.

The melt viscosity increase rate and the minimum melt viscosity of the prepreg 1 can be controlled by, for example, the content of the thermosetting resin composition in the prepreg 1, and the configuration of the resin component. The melt viscosity increase rate and the minimum melt viscosity of the prepreg 1 can be controlled by adjusting the proportion of the inorganic component in the resin component, the molecular weight and the glass transition temperature of a high molecular weight component included in the resin component, the type of the thermosetting resin and the mixing ratio thereof, and the type and mixing ratio of a curing accelerator. When the content of the thermosetting resin composition is large, the melt viscosity increase rate tends to be high.

Particularly, the molecular weight and glass transition temperature of the high molecular weight component included in the resin component, and the type and mixing ratio of the curing accelerator may significantly affect the behavior of the melt viscosity of the prepreg. For example, the glass transition temperature of the high molecular weight component may be lower than the temperature at which a curing reaction of the thermosetting resin composition is activated. The glass transition temperature of the high molecular weight component may be a temperature at which, when the dynamic viscoelasticity of a strip-shaped molded body of the high molecular weight component in a temperature range of 40 to 350° C. under the condition of a distance between chucks of 20 mm, a frequency of 10 Hz, and a temperature increase rate of 5° C./min, the tan 6 at that time exhibits the maximum value. For the measurement of the dynamic viscoelasticity, for example, a dynamic viscoelasticity measuring apparatus manufactured by UBM can be used. The temperature at which the curing reaction of the thermosetting resin composition is activated may be, for example, a temperature at which, when differential scanning calorimetry of the thermosetting resin composition is performed in a temperature range of 40 to 350° C. at a temperature increase rate of 5° C./min, the amount of heat generated by the curing reaction exhibits the maximum value. For the differential scanning calorimetry, for example, a differential scanning calorimetric apparatus manufactured by PerkinElmer Inc. can be used.

The glass transition temperature of the high molecular weight component may be lower by 10 to 80° C. than the temperature at which the curing reaction of the thermosetting resin composition is activated. From the viewpoint that the influence exerted by temperature variations at the time of laminating prepregs can be reduced, the glass transition temperature of the high molecular weight component may be lower by 20 to 80° C. than the temperature at which the curing reaction of the thermosetting resin composition is activated. From the viewpoint that voids at the time of laminating prepregs can be suppressed, the glass transition temperature of the high molecular weight component may be lower by 10 to 60° C. than the temperature at which the curing reaction of the thermosetting resin composition is activated. From the above, the glass transition temperature of the high molecular weight component may be lower by 20 to 60° C. than the temperature at which the curing reaction of the thermosetting resin composition is activated.

The thermosetting resin composition 12 may include a thermoplastic resin as the high molecular weight component. The thermoplastic resin is not particularly limited as long as it is a resin that is softened by heating, and may have one or more kinds of reactive functional groups at the molecular ends or in the molecular chain. Examples of the reactive functional group include an epoxy group, a hydroxyl group, a carboxyl group, an amino group, an amide group, an isocyanate group, an acryloyl group, a methacryloyl group, a vinyl group, and a maleic anhydride group.

The thermoplastic resin may be at least one kind selected from, for example, an acrylic resin, a polyamide resin, a polyimide resin, and a polyurethane resin.

The content of the thermoplastic resin may be, for example, 20 to 80% by mass based on the total mass of the components other than the inorganic filler in the thermosetting resin composition 12.

From the viewpoint of suppressing moisture absorption, the thermoplastic resin may include a resin having a siloxane group. For example, the acrylic resin, polyamide resin, polyimide resin, or polyurethane resin may have a siloxane group. The resin having a siloxane group may be a silicone resin.

From the viewpoint of suppressing outgases at the time of heating and from the viewpoint of adhesiveness, the thermoplastic resin may include a polyimide resin having a siloxane group. The polyimide resin having a siloxane group may be, for example, a polymer generated by a reaction between a siloxane diamine and a tetracarboxylic acid dianhydride, or a polymer generated by a reaction between a siloxane diamine and bismaleimide.

The siloxane diamine may be, for example, a compound represented by the following General Formula (5).

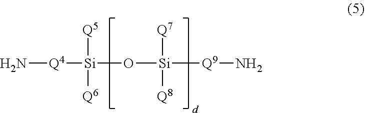

wherein in the formula, Q⁴ and Q⁹ each independently represent an alkylene group having 1 to 5 carbon atoms or a phenylene group which may have a substituent; Q⁵, Q⁶, Q⁷, and Q⁸ each independently represent an alkyl group having 1 to 5 carbon atoms, a phenyl group, or a phenoxy group; and d represents an integer of 1 to 5.

Examples of the siloxane diamine represented by Formula (5), in which d is 1, include 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, and 1,3-dimethyl-1,3-dimethoxy-1,3-bis(4-aminobutyl)disiloxane. Examples of the siloxane diamine represented by Formula (5), in which d is 2, include 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, and 1,1,3,3,5,5-hexapropyl-1,5-bis(3-aminopropyl)trisiloxane.

Examples of a commercially available product of the siloxane diamine include “PAM-E” (amino group equivalent 130 g/mol), “KF-8010” (amino group equivalent 430 g/mol), “X-22-161A” (amino group equivalent 800 g/mol), “X-22-161B” (amino group equivalent 1500 g/mol), “KF-8012” (amino group equivalent 2200 g/mol), “KF-8008” (amino group equivalent 5700 g/mol), “X-22-9409” (amino group equivalent 700 g/mol, side-chain phenyl type), “X-22-1660B-3” (amino group equivalent 2200 g/mol, side-chain phenyl type) (all manufactured by Shin-Etsu Chemical Co., Ltd.), “BY-16-853U” (amino group equivalent 460 g/mol), “BY-16-853” (amino group equivalent 650 g/mol), and “BY-16-853B” (amino group equivalent 2200 g/mol) (all manufactured by Dow Corning Toray Co., Ltd.), all of which have amino groups at both ends. These can be used singly or as mixtures of two or more kinds thereof. Among these, from the viewpoint of reactivity with a maleimide group, the siloxane diamine may be selected from “PAM-E”, “KF-8010”, “X-22-161A”, “X-22-161B”, “BY-16-853U”, and “BY-16-853”. From the viewpoint of dielectric characteristics, the siloxane diamine may be selected from “PAM-E”, “KF-8010”, “X-22-161A”, “BY-16-853U”, and “BY-16-853”. From the viewpoint of compatibility with a varnish, the siloxane diamine may be selected from “KF-8010”, “X-22-161A”, and “BY-16-853”.

The content of the siloxane group in the polyimide resin having a siloxane group is not particularly limited; however, from the viewpoints of reactivity and compatibility, the content may be 5 to 50% by mass based on the mass of the polyimide resin. The content of the siloxane group may be 5 to 30% by mass from the viewpoint of heat resistance, and may be 10 to 30% by mass from the viewpoint that the coefficient of moisture absorption can be further reduced.

The polyimide resin may be a polymer synthesized from a diamine other than a siloxane diamine, or may be a polymer synthesized from a combination of a siloxane diamine and another diamine.

The other diamine used as a raw material of the polyimide resin is not particularly limited, and examples thereof include aromatic diamines such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenyl ether methane, bis(4-amino-3,5-dimethylphenyl)methane, bis(4-amino-3,5-diisopropylphenyl)methane, 3,3′-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenyl sulfide, 3,4′-diaminodiphenyl sulfide, 4,4′-diaminodiphenyl sulfide, 3,3′-diaminodiphenyl ketone, 3,4′-diaminodiphenyl ketone, 4,4′-diaminodiphenyl ketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminophenoxy)phenyl) sulfide, bis(4-(4-aminophenoxy)phenyl) sulfide, bis(4-(3-aminophenoxy)phenyl)sulfone, bis(4-(4-aminophenoxy)phenyl)sulfone, 3,3′-dihydroxy-4,4′-diaminobiphenyl, and 3,5-diaminobenzoic acid; 1,3-bis(aminomethyl)cyclohexane, 2,2-bis(4-aminophenoxyphenyl)propane, an aliphatic ether diamine represented by the following General Formula (4), an aliphatic diamine represented by the following General Formula (11), and a diamine having a carboxyl group and/or a hydroxyl group.

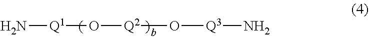

In Formula (4), Q¹, Q², and Q³ each independently represent an alkylene group having 1 to 10 carbon atoms; and b represents an integer of 2 to 80.

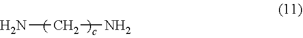

In Formula (11), c represents an integer of 5 to 20.

Examples of the aliphatic ether diamine represented by the above-described General Formula (4) include aliphatic diamines represented by the following General Formulas:

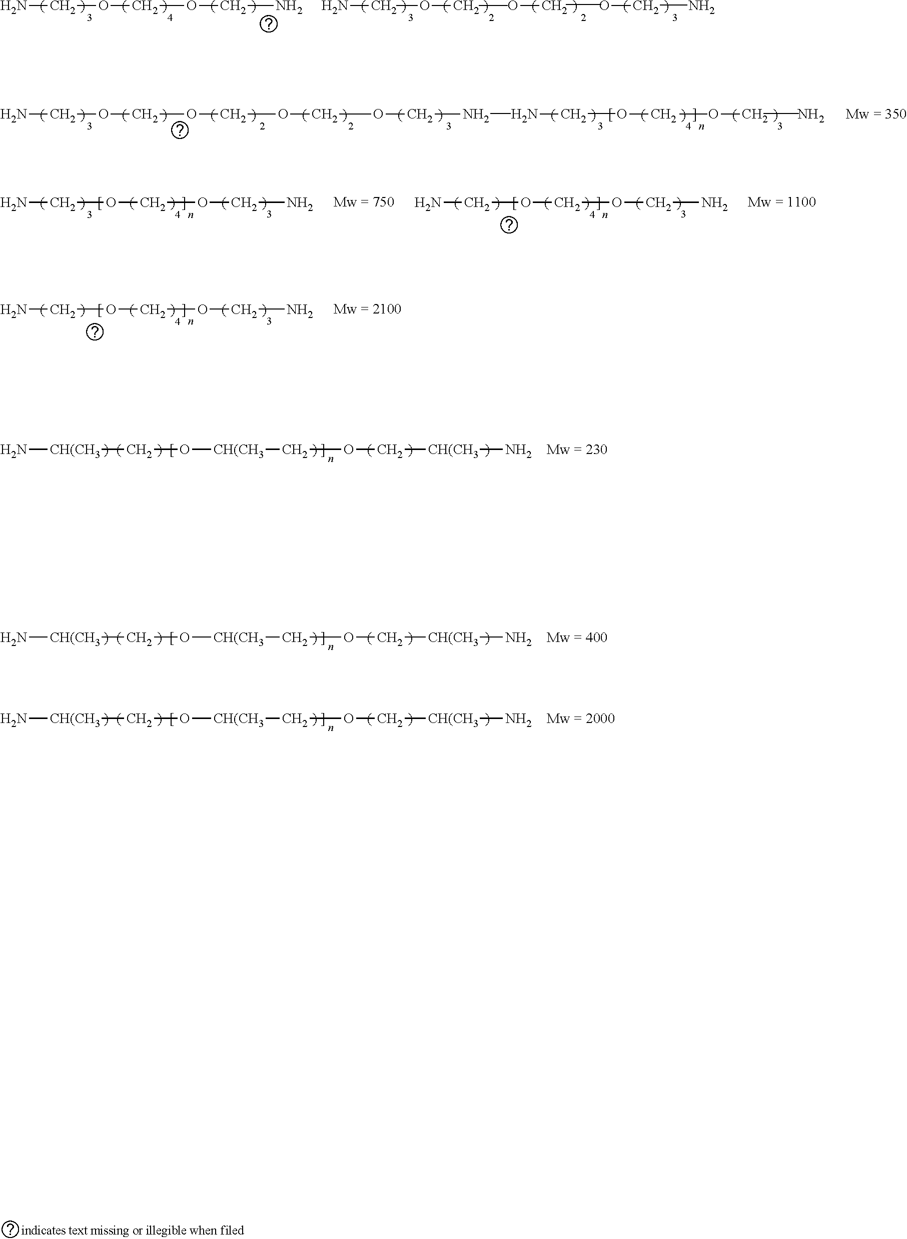

and an aliphatic ether diamine represented by the following General Formula (12).

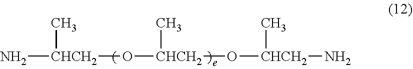

In Formula (12), e represents an integer of 0 to 80.

Examples of the aliphatic diamine represented by the above-described General Formula (11) include 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,11-diaminoundecane, 1,12-diaminododecane, and 1,2-diaminocyclohexane.

The diamines mentioned above as examples can be used singly or in combination of two or more kinds thereof.

As a raw material of the polyimide resin, a tetracarboxylic acid dianhydride can be used. Examples of the tetracarboxylic acid dianhydride include pyromellitic dianhydride, 3,3′,4,4′-biphenyltetracarboxylic acid dianhydride, 2,2′,3,3′-biphenyltetracarboxylic acid dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl) ether dianhydride, benzene-1,2,3,4-tetracarboxylic acid dianhydride, 3,4,3′,4′-benzophenonetetracarboxylic acid dianhydride, 2,3,2′,3′-benzophenonetetracarboxylic acid dianhydride, 3,3,3′,4′-benzophenonetetracarboxylic acid dianhydride, 1,2,5,6-naphthalenetetracarboxylic acid dianhydride, 1,4,5,8-naphthalenetetracarboxylic acid dianhydride, 2,3,6,7-naphthalenetetracarboxylic acid dianhydride, 1,2,4,5-naphthalenetetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanethrene-1,8,9,10-tetracarboxylic acid dianhydride, pyrazine-2,3,5,6-tetracarboxylic acid dianhydride, thiophene-2,3,5,6-tetracarboxylic acid dianhydride, 2,3,3′,4′-biphenyltetracarboxylic acid dianhydride, 3,4,3′,4′-biphenyltetracarboxylic acid dianhydride, 2,3,2′,3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylene bis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutanetetracarboxylic acid dianhydride, bis(exo-bicyclo[2,2,1]heptane-2,3-dicarboxylic acid dianhydride, bicyclo[2,2,2]-oct-7-ene-2,3,5,6-tetracarboxylic acid dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4′-bis(3,4-dicarboxyphenoxy)diphenyl sulfide dianhydride, 1,4-bis(2-hydroxyhexafluoroisopropyl)benzene bis(trimellitic anhydride), 1,3-bis(2-hydroxyhexafluoroisopropyl)benzene bis(trimellitic anhydride), 5-(2,5-dioxotetrahydrofuryl)-3-methyl-3-cyclohexene-1,2-dicarboxylic acid dianhydride, tetrahydrofuran-2,3,4,5-tetracarboxylic acid dianhydride, and a tetracarboxylic acid dianhydride represented by the following General Formula (7).

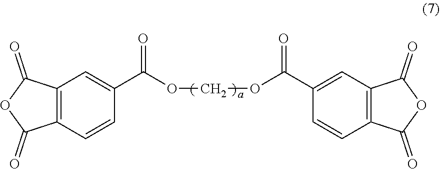

In Formula (7), a represents an integer of 2 to 20.

Examples of the tetracarboxylic acid dianhydride represented by the above-described General Formula (7) include, specifically, 1,2-(ethylene) bis(trimellitate anhydride), 1,3-(trimethylene) bis(trimellitate anhydride), 1,4-(tetramethylene) bis(trimellitate anhydride), 1,5-(pentamethylene) bis(trimellitate anhydride), 1,6-(hexamethylene) bis(trimellitate anhydride), 1,7-(heptamethylene) bis(trimellitate anhydride), 1,8-(octamethylene) bis(trimellitate anhydride), 1,9-(nonamethylene) bis(trimellitate anhydride), 1,10-(decamethylene) bis(trimellitate anhydride), 1,12-(dodecamethylene) bis(trimellitate anhydride), 1,16-(hexadecamethylene) bis(trimellitate anhydride), and 1,18-(octadecamethylene) bis(trimellitate anhydride), each of which can be synthesized from trimellitic anhydride monochloride and a corresponding diol.

From the viewpoint of imparting satisfactory dissolubility in solvents and moisture resistance reliability, the tetracarboxylic acid dianhydride can include a tetracarboxylic acid dianhydride represented by the following General Formula (6) or (8).

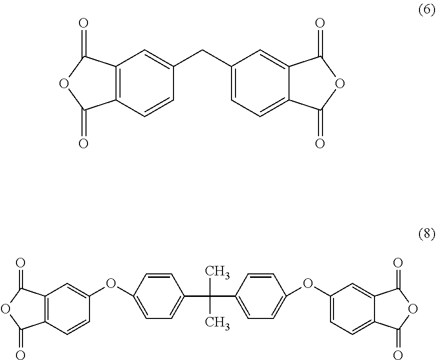

Tetracarboxylic acid dianhydrides such as described above can be used singly or in combination of two or more kinds thereof.

As a raw material of the polyimide resin, bismaleimide can be used. The bismaleimide is not particularly limited; however, examples thereof include bis(4-maleimidophenyl)methane, polyphenylmethane maleimide, bis(4-maleimidophenyl) ether, bis(4-maleimidophenyl)sulfone, 3,3-dimethyl-5,5-diethyl-4,4-diphenylmethane bismaleimide, 4-methyl-1,3-phenylene bismaleimide, m-phenylene bismaleimide, and 2,2-bis(4-(4-maleimidophenoxy)phenyl)propane. These can be used singly or as mixtures of two or more kinds thereof. The bismaleimide may also be selected from bis(4-maleimidophenyl)methane, bis(4-maleimidophenyl)sulfone, 3,3-dimethyl-5,5-diethyl-4,4-diphenylmethane bismaleimide, and 2,2-bis(4-(4-maleimidophenoxy)phenyl)propane, which are highly reactive and can further improve dielectric characteristics and wireability, and the bismaleimide may be selected from 3,3-dimethyl-5,5-diethyl-4,4-diphenylmethane bismaleimide, bis(4-maleimidophenyl)methane, and 2,2-bis(4-(4-maleimidophenoxy)phenyl)propane from the viewpoint of dissolubility in solvents, may be selected from bis(4-maleimidophenyl)methane from the viewpoint of being inexpensive, or may be selected from 2,2-bis(4-(4-maleimidophenoxy)phenyl)propane and BMI-3000 (product name) of Designer Molecules Inc., from the viewpoint of wireability.

The thermosetting resin composition 12 includes a thermosetting resin, which is a compound that forms a crosslinked polymer by heating. A thermosetting resin usually has a reactive functional group that causes a crosslinking reaction. The reactive functional group may be, for example, an epoxy group, a hydroxyl group, a carboxyl group, an amino group, an amide group, an isocyanate group, an acryloyl group, a methacryloyl group, a vinyl group, a maleic anhydride group, or a combination of these.

The content of the thermosetting resin may be, for example, 20 to 80% by mass based on the total mass of the components other than the inorganic filler in the thermosetting resin composition 12.

The thermosetting resin composition 12 may include an epoxy resin as the thermosetting resin. The epoxy resin may be a compound including two or more epoxy groups. The epoxy resin may be a phenol glycidyl ether type epoxy resin from the viewpoints of curability and the characteristics of the cured product. Examples of the phenol glycidyl ether type epoxy resin include a biphenyl aralkyl type epoxy resin, a bisphenol A type (or AD type, S type, or F type) glycidyl ether, a hydrogenated bisphenol A type glycidyl ether, an ethylene oxide adduct bisphenol A type glycidyl ether, a propylene oxide adduct bisphenol A type glycidyl ether, glycidyl ether of a phenol novolac resin, glycidyl ether of a cresol novolac resin, glycidyl ether of a bisphenol A novolac resin, glycidyl ether of a naphthalene resin, a trifunctional (or tetrafunctional) glycidyl ether, and glycidyl ether of a dicyclopentadiene phenol resin. Other examples of the epoxy resin include glycidyl ester of a dimer acid, a trifunctional (or tetrafunctional) glycidylamine, and glycidylamine of a naphthalene resin. These are used singly or in combination of two or more kinds thereof.

The thermosetting resin composition 12 may include an acrylate compound as the thermosetting resin. The acrylate compound may have two or more (meth)acryloyl groups. Examples of the acrylate compound include diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N,N-dimethylacrylamide, N-methylolacrylamide, triacrylate of tris(p-hydroxyethyl) isocyanurate, a compound represented by the following General Formula (13), urethane acrylate or urethane methacrylate, and urea acrylate.

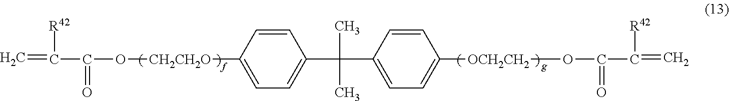

In Formula (13), R⁴¹ and R⁴² each independently represent a hydrogen atom or a methyl group; and f and g each independently represent an integer of 1 or greater. The radiation-polymerizable compound having a glycol skeleton, which is represented by Formula (13), can impart solvent resistance after curing. Urethane acrylate, urethane methacrylate, isocyanuric acid-modified di-/tri-acrylate and methacrylate can impart high adhesiveness after curing.

The thermosetting resin composition 12 may include a thermosetting elastomer selected from a styrene-based elastomer, an olefin-based elastomer, a urethane-based elastomer, a polyester-based elastomer, a polyamide-based elastomer, an acrylic elastomer, and a silicone-based elastomer as the thermosetting resin. A thermosetting elastomer is composed of a hard segment component and a soft segment component, and generally the hard segment component contributes to heat resistance and strength, while the soft segment component contributes to flexibility and toughness. These thermosetting elastomers can be used singly or as mixtures of two or more kinds thereof. The thermosetting elastomer may be selected from a styrene-based elastomer, an olefin-based elastomer, a polyamide-based elastomer, and a silicone-based elastomer from the viewpoints of heat resistance and insulation reliability, or may be selected from a styrene-based elastomer and an olefin-based elastomer from the viewpoint of dielectric characteristics.

The thermosetting elastomer has a reactive functional group at the molecular ends or in the molecular chain. Examples of the reactive functional group include an epoxy group, a hydroxyl group, a carboxyl group, an amino group, an amide group, an isocyanate group, an acryloyl group, a methacryloyl group, a vinyl group, and a maleic anhydride group. From the viewpoints of compatibility, wireability, and the like, the reactive functional group of the thermosetting elastomer may be an epoxy group, an amino group, an acryloyl group, a methacryloyl group, a vinyl group, or a maleic anhydride group, or may be an epoxy group, an amino group, or a maleic anhydride group. The content of the thermosetting elastomer may be 10 to 70% by mass based on the mass of the thermosetting resin composition, or may be 20 to 60% by mass from the viewpoints of the dielectric characteristics and the compatibility of the varnish.

The thermosetting resin composition may include a curing accelerator that accelerates a curing reaction of the thermosetting resin, as necessary. Examples of the curing accelerator include a peroxide, an imidazole compound, an organic phosphorus-based compound, a secondary amine, a tertiary amine, and a quaternary ammonium salt. These can be used singly or in combination of two or more kinds thereof. In a case where the thermosetting resin is an epoxy resin, the curing accelerator may be, for example, an imidazole compound.

The content of the curing accelerator may be 0.1 to 10% by mass based on the total mass of the components other than the inorganic filler in the thermosetting resin composition, or may be 0.5 to 5% by mass or 0.75 to 3% by mass from the viewpoints of the dielectric characteristics and the handleability of the prepreg.

The thermosetting resin composition 12 may include an adhesion aid. Examples of the adhesion aid include a silane coupling agent, a triazole compound, and a tetrazole compound.

The silane coupling agent may be a compound having a nitrogen atom in order to improve close adhesiveness to metals. Examples of the silane coupling agent include N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethylbutylidene)propylamine, N-phenyl-3-aminopropyltrimethoxysilane, tris(trimethoxysilylpropyl) isocyanurate, 3-ureidopropyltrialkoxysilane, and 3-isocyanatopropyltriethoxysilane.

From the viewpoints of the effect brought by addition, heat resistance, production cost, and the like, the content of the silane coupling agent may be 0.1 to 20% by mass based on the total mass of the components other than the inorganic filler in the thermosetting resin composition 12.

Examples of the triazole compound include 2-(2′-hydroxy-5′-methylphenyl)benzotriazole, 2-(2′-hydroxy-3′-tert-butyl-5′-methylphenyl)-5-chlorobenzotriazole, 2-(2′-hydroxy-3′,5′-di-tert-amylphenyl)benzotriazole, 2-(2′-hydroxy-5′-tert-octylphenyl)benzotriazole, 2,2′-methylenebis[6-(2H-benzotriazol-2-yl)-4-tert-octylphenol], 6-(2-benzotriazolyl)-4-tert-octyl-6′-tert-butyl-4′-methyl-2,2′-methylenebisphenol, 1,2,3-benzotriazole, 1-[N,N-bis(2-ethylhexyl)aminomethyl]benzotriazole, carboxybenzotriazole, 1-[N,N-bis(2-ethylhexyl)aminomethyl]methylbenzotriazole, and 2,2′-[[(methyl-1H-benzotriazol-1-yl)methyl]imino]bisethanol.

Examples of the tetrazole compound include 1H-tetrazole, 5-amino-1H-tetrazole, 5-methyl-1H-tetrazole, 5-phenyl-1H-tetrazole, 1-methyl-5-ethyl-1H-tetrazole, 1-methyl-5-mercapto-1H-tetrazole, 1-phenyl-5-mercapto-1H-tetrazole, 1-(2-dimethylaminoethyl)-5-mercapto-1H-tetrazole, 2-methoxy-5-(5-trifluoromethyl-1H-tetrazol-1-yl)-benzaldehyde, 4,5-di(5-tetrazolyl)-[1,2,3]triazole, and 1-methyl-5-benzoyl-1H-tetrazole.

From the viewpoints of the effect brought by addition, heat resistance, and production cost, the content of the triazole compound and the tetrazole compound may be 0.1 to 20% by mass based on the total mass of the components other than the inorganic filler in the thermosetting resin composition 12.

The silane coupling agent, the triazole compound, and the tetrazole compound may be each used singly or in combination.

The thermosetting resin composition 12 may include an ion scavenger. As ionic impurities in the organic insulating layer are adsorbed by the ion scavenger, the insulation reliability at the time of moisture absorption can be improved. Examples of the ion scavenger include compounds known as copper inhibitors for preventing copper from ionizing and dissolving, such as a triazinethiol compound and a phenol-based reducing agent; and bismuth-based, antimony-based, magnesium-based, aluminum-based, zirconium-based, calcium-based, titanium-based, and tin-based inorganic compounds, or mixtures thereof.

Examples of a commercially available product of the ion scavenger include inorganic ion scavengers (trade names: IXE-300 (antimony-based), IXE-500 (bismuth-based), IXE-600 (antimony-bismuth mixture), IXE-700 (magnesium-aluminum mixture), IXE-800 (zirconium-based), and IXE-1100 (calcium-based)). These may be used singly, or two or more kinds thereof may be used as a mixture.

From the viewpoints of the effect brought by addition, heat resistance, production cost, and the like, the content of the ion scavenger may be 0.01 to 10% by mass based on the total mass of the components other than the inorganic filler in the thermosetting resin composition 12.

The thermosetting resin composition 12 may include a filler in order to impart low hygroscopic properties and low moisture permeability. The filler may be an inorganic filler, an organic filler, or a combination of these. An inorganic filler can be added for the purpose of imparting thermal conductivity, low thermal expansion properties, low hygroscopic properties, and the like to the insulating substrate. An organic filler can be added for the purpose of imparting toughness and the like to the insulating substrate.

Examples of the inorganic filler include alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, ceramics, and carbon. Examples of the organic filler include a rubber-based filler. These inorganic fillers or organic fillers can be used singly or in combination of two or more kinds thereof. The thermosetting resin composition 12 may include a silica filler and/or an alumina filler.

The average particle size of the filler may be 10 μm or less or 5 μm or less. The maximum particle size of the filler may be 30 μm or less or 20 μm or less. When the average particle size is more than 10 μm, and the maximum particle size is more than 30 μm, there is a tendency that an effect of improving fracture toughness is less likely to be obtained. The lower limits of the average particle size and the maximum particle size are not particularly limited; however, the lower limits are usually 0.001 μm.

The filler may satisfy both conditions of an average particle size of 10 μm or less and a maximum particle size of 30 μm or less. A filler having a maximum particle size of 30 μm or less but having an average particle size of greater than 10 μm tends to relatively decrease the adhesive strength. A filler having an average particle size of 10 μm or less but a maximum particle size of greater than 30 μm tends to increase the variations in adhesive strength.

The average particle size and the maximum particle size of the filler can be measured by, for example, a method of measuring the particle sizes of about several filler particles by using a scanning electron microscope (SEM). In the case of a measurement method of using a SEM, for example, a cured product obtained by heating and curing the thermosetting resin composition may be produced, and a cross-section at the center portion of the cured product may be observed with a SEM. The existence probability of filler particles having a particle size of 30 μm or less may be 80% or greater of the entire filler.

The content of the filler (particularly, inorganic filler) may be, for example, 40 to 300% by mass based on the total mass of the components other than the filler in the thermosetting resin composition 12.

In order to achieve storage stability, prevention of electromigration, and prevention of corrosion of metal conductor circuits, the thermosetting resin composition may include an oxidation inhibitor. Examples of the oxidation inhibitor include benzophenone-based, benzoate-based, hindered amine-based, benzotriazole-based, or phenol-based oxidation inhibitors. From the viewpoints of an effect brought by addition, heat resistance, cost, and the like, the content of the oxidation inhibitor may be 0.01 to 10% by mass based on the total mass of the components other than the inorganic filler in the thermosetting resin composition 12.

The dielectric constant at 10 GHz of a cured product of the thermosetting resin composition 12 may be 3.0 or less, and from the viewpoint that reliability of electric signals can be further improved, the dielectric constant at 10 GHz may also be 2.8 or less. The dielectric loss tangent at 10 GHz of a cured product of the thermosetting resin composition 12 may be 0.005 or less. The dielectric constant can be measured by using a test piece having a length of 60 mm, a width of 2 mm, and a thickness of 300 μm, which is a cured product of the thermosetting resin composition. The test piece may be vacuum-dried at 30° C. for 6 hours before measurement. The dielectric loss tangent can be calculated from the resonance frequency obtained at 10 GHz and the unloaded Q value. The measuring apparatus may include a vector type network analyzer E8364B manufactured by Keysight Technologies, and CP531 (10 GHz resonator) and CPMAV2 (program) manufactured by Kanto Electronics Application Development Co., Ltd. The measurement temperature may be 25° C.

The glass transition temperature of a cured product formed by thermal curing of the thermosetting resin composition 12 may be 120° C. or higher from the viewpoint of suppressing cracks during temperature cycles, or may be 140° C. or higher from the viewpoint that stress on the wiring lines can be reduced. The glass transition temperature of the cured product may be 240° C. or lower from the viewpoint of enabling lamination at low temperatures, or may be 220° C. or lower from the viewpoint that curing shrinkage can be suppressed.

The width of the prepreg 1 may be, for example, 200 to 1300 mm. The thickness of the prepreg 1 may be, for example, 15 to 300 μm. When the thickness of the prepreg 1 is less than 15 μm, surface unevenness originating from the inorganic fiber base material 11 remains, and flatness tends to be relatively reduced. When the thickness of the prepreg 1 is more than 300 μm, warpage tends to increase.

The prepreg 1 can be obtained by, for example, a method including impregnating the inorganic fiber base material 11 with a resin varnish including the thermosetting resin composition 12 and a solvent, and removing the solvent from the resin varnish.

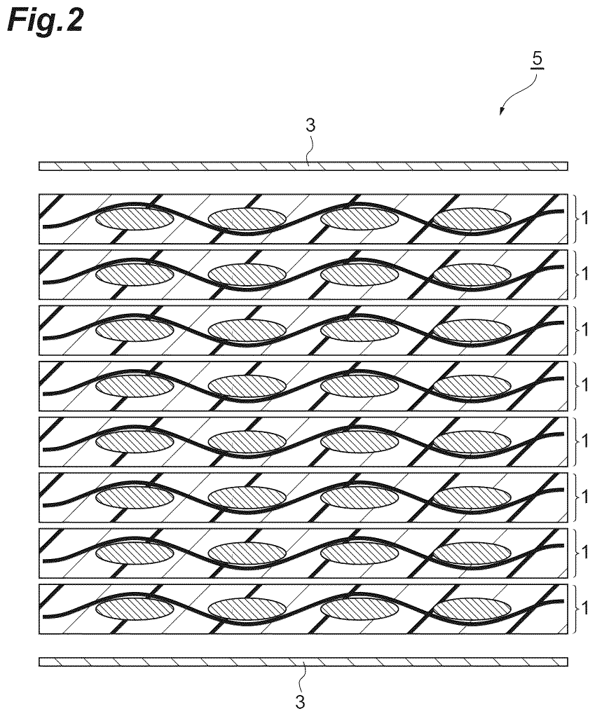

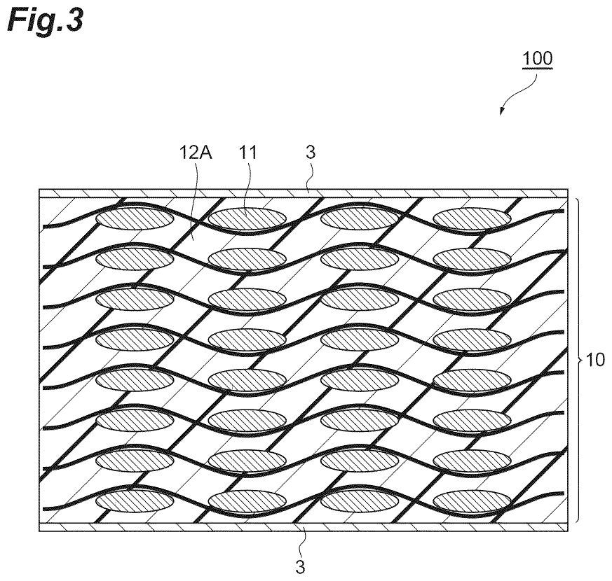

FIG. 2 and FIG. 3 are cross-sectional views illustrating an example of a method for manufacturing a substrate material for a semiconductor package. The method shown in FIG. 2 and FIG. 3 includes a step of performing a molding treatment including increasing the temperature of a laminated body 5 in which a metal foil 3, two or more sheets of a prepreg 1, and a metal foil 3 are laminated in this order, while pressurizing the laminated body 5 to form a substrate material 100 for a semiconductor package, the substrate material 100 having an insulating substrate 10 formed by integrating two or more sheets of the prepreg 1, and the metal foil 3 provided on both faces of the insulating substrate 10. An insulating resin layer may be provided between the metal foil 3 and the laminated body 5.

In the molding treatment for forming the substrate material 100 for a semiconductor package, the laminated body 5 is heated and pressurized under the heating condition in which the melt viscosity of the prepreg 1 increases up to 1000×10³ Pa·s at a rate of 55×10³ Pa·s/min or greater from the time point at which the minimum melt viscosity is exhibited. According to the molding treatment under such heating conditions, a substrate material 100 for a semiconductor package with small variations in thickness can be easily manufactured. By using the substrate material 100 for a semiconductor package, a semiconductor device that transmits high-frequency signals, in which fine wiring lines are formed and chips having fine bumps are connected, can be manufactured by high reliability and productivity. The obtained substrate material 100 for a semiconductor package is also excellent from the viewpoint of reducing warpage.

From the viewpoint of further suppressing variations in the line width, the melt viscosity increase rate exhibited by the prepreg 1 under the heating condition of the molding treatment for forming the substrate material 100 for a semiconductor package may be 60×10³ Pa·s/min or greater, 65×10³ Pa·s/min or greater, 70×10³ Pa·s/min or greater, 75×10³ Pa·s/min or greater, 80×10³ Pa·s/min or greater, 85×10³ Pa·s/min or greater, 90×10³ Pa·s/min or greater, 95×10³ Pa·s/min or greater, 100×10³ Pa·s/min or greater, 105×10³ Pa·s/min or greater, or 110×10³ Pa·s/min or greater, and may be 200×10³ Pa·s/min or less, 190×10³ Pa·s/min or less, 180×10³ Pa·s/min or less, 170×10³ Pa·s/min or less, or 160×10³ Pa·s/min or less.

From the viewpoint of further suppressing variations in the line width, the minimum melt viscosity exhibited by the prepreg 1 under the heating condition of the molding treatment for forming the substrate material 100 for a semiconductor package may be 10×10³ Pa·s or less, 9.0×10³ Pa·s or less, 8.0×10³ Pa·s or less, 7.0×10³ Pa·s or less, 6.0×10³ Pa·s or less, 5.0×10³ Pa·s or less, or 4.0×10³ Pa·s or less, and may be 1.0×10³ Pa·s or greater.

The temperature at which the prepreg 1 exhibits the minimum melt viscosity in the molding treatment may be 80° C. or higher or 120° C. or higher, and may be 200° C. or lower or 180° C. or lower.

Two or more sheets of the prepreg 1 may be identical with or different from each other. In a case where two or more sheets of different prepregs 1 are used, at least the prepreg 1 located on the outermost side (metal foil 3 side) among them may have the melt viscosity increase rate and the minimum melt viscosity within the above-described ranges.

Under the heating condition of the molding treatment for forming the substrate material 100 for a semiconductor package, the melt viscosity of the prepreg 1 decreases to the minimum melt viscosity and then increases with the progress of the curing reaction. Generally, when the temperature increase rate is large, the minimum melt viscosity of the prepreg 1 tends to be lowered. The temperature increase rate may be, for example, 2° C./min or greater, 3° C./min or greater, or 4° C./min or greater, and may be 8° C./min or less, 7° C./min or less, or 6° C./min or less. The temperature increase rate may be constant or may vary. The temperature of the laminated body 5 may be increased, for example, starting from a temperature in the range of, for example, 20 to 120° C.

The heating condition of the molding treatment for forming the substrate material 100 for a semiconductor package may include increasing the temperature of the laminated body 5 to the molding temperature at a predetermined temperature increase rate, and maintaining the temperature of the laminated body 5 at the molding temperature. The molding temperature in this case may be, for example, 100 to 250° C., or 150 or 00° C. The time for heating and pressurization at the molding temperature may be, for example, 0.1 to 5 hours.

During the molding treatment, usually, the laminated body 5 is continuously pressurized. During the molding treatment, the pressure applied to the laminated body 5 may be, for example, 0.2 to 10 MPa.

From the viewpoint of electrical conductivity, the metal foil 3 may include copper, gold, silver, nickel, platinum, molybdenum, ruthenium, aluminum, tungsten, iron, titanium, chromium, or an alloy including at least one of these metal elements. The metal foil 3 may be a copper foil or an aluminum foil, and may be a copper foil. An insulating resin layer may be provided on the surface on the prepreg 1 side of the metal foil 3.

The apparatus for performing the molding treatment of heating and pressurizing the laminated body 5 may be a heat pressing apparatus, and may be, for example, a multistage press, a multistage vacuum press, continuous molding, or an autoclave molding machine.

In a case where the inorganic fiber base material 11 constituting the prepreg 1 is a woven fabric including inorganic fibers, the two or more sheets of the prepreg may be laminated in a direction that is parallel to the direction of the inorganic fibers, or may be laminated in a direction that is perpendicular to the direction of the inorganic fibers.

In a case where the molding treatment for forming the substrate material for a semiconductor package is heat pressing, a metal plate may be disposed on a surface of the metal foil 3, the surface being on the opposite side of the prepreg 1. The thickness of the metal plate may be 0.5 mm to 7 mm. When the metal plate is thinner than 0.5 mm, there is a possibility that the metal plate may be easily moved. When the metal plate is thicker than 7 mm, there is a possibility that handleability may deteriorate. The metal plate may be, for example, a stainless steel plate.

The standard deviation of the thickness measured at any number of sites within an area of any size within the metal plate may be 4 μm or less. The standard deviation of the thickness of the metal plate can be determined by the following formula, for example, when the thicknesses obtained by measuring the thickness at any n sites on the metal plate are designated as T₁, T₂, . . . , Tₙ, respectively, and the average thickness of the metal plate is designated as T.

$$σ = \sqrt{\frac{1}{n} {\sum }_{i = 1}^{n} {( {T}_{i} - T )}^{2}}$$

In the heat pressing for forming the substrate material for a semiconductor package, a cushioning material may be disposed on a surface of the metal foil 3, the surface being on the opposite side of the prepreg 1. The cushioning material may be, for example, a paper material having a thickness of about 0.2 mm. It is also acceptable to use both the cushioning material and the metal plate.

The molding treatment for forming the substrate material for a semiconductor package may be carried out a plurality of times in divided stages. For example, the method for manufacturing the substrate material for a semiconductor package may further include a step of laminating one or more sheets of an additional prepreg on the insulating substrate formed by a first molding treatment, and forming a second laminated body; and a step of forming an insulating substrate after two times of lamination, which includes the portion formed from the additional prepreg, by a molding treatment including increasing the temperature of the second laminated body while pressurizing the second laminated body. In this case, the additional prepreg may also include an inorganic fiber base material and a thermosetting resin composition impregnated into the inorganic fiber base material. The content of the thermosetting resin composition may be 40% by mass or more and 80% by mass or less based on the mass of the additional prepreg. The additional prepreg may be identical with or different from the prepreg constituting the laminated body in the first molding treatment. In the molding treatment for forming the insulating substrate after two times of lamination, the temperature of the second laminated body is increased under the heating condition in which the melt viscosity of the additional prepreg increases up to 1000×10³ Pa·s at a rate of 55×10³ Pa·s/min or greater from the time point at which the minimum melt viscosity is exhibited. Usually, the metal foil is removed from the first laminated body before the additional prepreg is laminated on the insulating substrate.

The width of the substrate material 100 for a semiconductor package may be 200 to 1300 mm from the viewpoint of productivity. The thickness of the substrate material 100 for a semiconductor package may be 200 to 1500 μm.

The substrate material 100 for a semiconductor package can have a thickness with small variations. For example, the standard deviation of the thickness of the substrate material for a semiconductor package may be 4 μm or less, 3.5 μm or less, 3 μm or less, 2.5 μm or less, or 2 μm or less, and may be 0.1 μm or greater. The standard deviation of the thickness of the substrate material 100 for a semiconductor package can be a value determined by a method including: dividing the entire principal surface of the substrate material for a semiconductor package into a plurality of square areas that measures 50 mm on each side, measuring the thickness at four sites at a position 2 mm inward from the four corners of each area; calculating the value of the standard deviation of thickness by using the thickness values at the four sites measured in each area as a population; and setting the maximum value among the values of the standard deviation of thickness calculated in each area as the standard deviation of thickness of the substrate material 100 for a semiconductor package. The thickness is measured by using, for example, a micrometer.

The substrate material 100 for a semiconductor package can be used as, for example, a core material for forming a wiring substrate for a semiconductor package where semiconductor chips are mounted. By utilizing the metal foil 3 of the substrate material 100 for a semiconductor package, or by removing the metal foil 3 and forming wiring lines on the exposed insulating substrate, a wiring substrate for a semiconductor package having fine wiring lines can be manufactured.

The wiring substrate for a semiconductor package can be obtained by, for example, a method including wiring lines on the metal foil 3 by a subtractive method, or a method including removing the metal foil 3 as necessary and then forming wiring lines by a semi-additive method. If necessary, a through-hole penetrating through the insulating substrate 10 may be formed, and a conductive via filling the through-hole may be formed.

A semiconductor package is manufactured by mounting a semiconductor chip, a memory, and the like at predetermined positions on the wiring substrate for a semiconductor package. Since the wiring substrate for a semiconductor package obtained by using the substrate material for a semiconductor package according to the present disclosure has small variations in thickness, the yield of the step of mounting a semiconductor chip tends to be improved. Furthermore, a semiconductor chip having minute solder bumps can be more easily mounted on the wiring substrate.

A buildup layer may be formed on the wiring substrate for a semiconductor package. In that case, wiring lines that are connected to semiconductor chips can be formed on the buildup layer. The method for forming a buildup layer may be, for example, a subtractive process, a full additive process, a Semi Additive Process (SAP), a modified Semi Additive Process (m-SAP), or a trench process.

The trench process is a method including forming a buildup material or photosensitive insulating material layer having a pattern including groove parts on a wiring substrate, and filling the groove parts with a conductive material. The conductive material formed on areas other than the groove parts is removed by a method such as CMP or a fly-cutting method. When the variations in the thickness of the substrate material for a semiconductor package are small, the conductive material formed on areas other than the groove parts can be easily removed while leaving the conductive material filled in the groove parts.

### EXAMPLES

The present invention is not intended to be limited to the following Examples.

### 1. Production of Prepreg

### Prepreg A

Into a flask equipped with a stirrer, a thermometer, and a nitrogen purging apparatus, 24 g of silicone diamine (trade name “KF-8010”, manufactured by Shin-Etsu Silicone Co., Ltd.), 240 g of bis(4-maleimidophenyl)methanol, and 400 g of propylene glycol monomethyl ether were introduced. The formed reaction liquid was heated at 115° C. for 4 hours to produce a polyimide resin 1. Thereafter, the temperature of the reaction liquid was increased to 130° C. at normal pressure to be concentrated, and a polyimide resin solution having a concentration of 60% by mass was obtained.

The obtained polyimide resin solution (polyimide resin content: 50 g), an epoxy resin solution in which 40 g of a biphenylaralkyl type epoxy resin (trade name “NC-3000-H”, manufactured by Nippon Kayaku Co., Ltd.) was dissolved in propylene glycol monomethyl ether, 0.5 g of a curing accelerator (trade name “2P4MHZ-PW”, manufactured by SHIKOKU CHEMICALS CORPORATION), a silica slurry including 40 g of a silica filler (trade name “SC2050-KNK”, manufactured by ADMATECHS COMPANY LIMITED), and N-methylpyrrolidone were mixed, and the mixture was stirred for 30 minutes to obtain a resin varnish. The total concentration of the polyimide resin and the epoxy resin in the resin varnish was 65% by mass. The obtained resin varnish was impregnated into a glass cloth (thickness 0.1 mm) formed by E-glass fibers and was heated and dried at 150° C. for 10 minutes to obtain a prepreg A having a resin content (content of the thermosetting resin composition) of 50% by mass.

### Prepreg B

A prepreg B was produced in the same manner as in the case of the prepreg A, except that the resin content was changed to 70% by mass.

### Prepreg C

Into a flask equipped with a stirrer, a thermometer, and a nitrogen purging apparatus, 10.3 g of 2,2-bis(4-(4-aminophenoxy)phenyl)propane, 4.1 g of 1,4-butanediol bis(3-aminopropyl) ether (trade name “B-12”, manufactured by Tokyo Chemical Industry Co., Ltd.), and 101 g of N-methylpyrrolidone were introduced. Next, 20.5 g of 1,2-(ethylene) bis(trimellitate anhydride) was added thereto. The formed reaction liquid was stirred at room temperature for 1 hour, and then the flask was fitted with a reflux condenser with a water receptacle. While nitrogen gas was blown in, the temperature of the reaction liquid was increased to 180° C., and the temperature was maintained for 5 hours to allow the reaction to proceed while removing water, to produce a polyimide resin 2. The polyimide resin solution was cooled to room temperature.

The obtained polyimide resin solution (polyimide resin content: 50 g), an epoxy resin solution in which 40 g of a biphenylaralkyl type epoxy resin (trade name “NC-3000-H”, manufactured by Nippon Kayaku Co., Ltd.) was dissolved in N-methylpyrrolidone, 0.5 g of a curing accelerator (imidazole compound, trade name “2P4MHZ-PW”, manufactured by SHIKOKU CHEMICALS CORPORATION), a silica slurry including 40 g of a silica filler (trade name “SC2050-KNK”, manufactured by ADMATECHS COMPANY LIMITED), and N-methylpyrrolidone were mixed, and the mixture was stirred for 30 minutes to obtain a resin varnish. The total concentration of the polyimide resin and the epoxy resin in the resin varnish was 65% by mass. The obtained resin varnish was impregnated into a glass cloth (thickness 0.1 mm) formed by E-glass fibers and was heated and dried at 150° C. for 10 minutes to form a prepreg C having a resin content of 50% by mass.

### Prepreg D

A prepreg D was produced in the same manner as in the case of the prepreg C, except that the resin content was changed to 70% by mass.

### Prepreg E

A prepreg E was produced in the same manner as in the case of the prepreg A, except that the resin content was changed to 35% by mass.

### Prepreg F

A polyimide solution including the polyimide resin 1 (polyimide content: 50 g), an epoxy resin solution in which 60 g of a biphenylaralkyl type epoxy resin (trade name “NC-3000-H”, manufactured by Nippon Kayaku Co., Ltd.) was dissolved in propylene glycol monomethyl ether, 1.5 g of a curing accelerator (imidazole compound, trade name “2P4MZ”, manufactured by SHIKOKU CHEMICALS CORPORATION), 50 g of a silica slurry including 50 g of a silica filler (trade name “SC2050-KNK”, manufactured by ADMATECHS COMPANY LIMITED), and N-methylpyrrolidone were mixed, and the mixture was stirred for 30 minutes to obtain a resin varnish. The total concentration of the polyimide resin and the epoxy resin in the resin varnish was 65% by mass. The obtained resin varnish was impregnated into a glass cloth (thickness 0.1 mm) formed by E-glass fibers and was heated and dried at 150° C. for 10 minutes to obtain a prepreg F having a resin content of 50% by mass.

### Prepreg G

A prepreg G was produced in the same manner as in the case of the prepreg A, except that the resin content was changed to 40% by mass.

### Prepreg H

A prepreg H was produced in the same manner as in the case of the prepreg A, except that the resin content was changed to 80% by mass.

### 2. Minimum Melt Viscosity of Prepreg, and Melt Viscosity Increase Rate

A produced prepreg was sandwiched between two sheets of parallel plates having a diameter of 8 mm, and the melt viscosity (complex viscosity) of the laminated body was measured by using a viscoelasticity measuring apparatus (ARES, manufactured by Rheometric Scientific Far East Ltd.) in a shear mode at a frequency of 10 Hz under temperature increase conditions of the following condition A. From the measurement results, the minimum melt viscosity was determined. Furthermore, the melt viscosity increase rate per minute was determined for the period in which the melt viscosity increased up to 1000×10³ Pa·s from the time point at which the minimum melt viscosity was exhibited. For the prepregs A and D, the minimum melt viscosity and the melt viscosity increase rate in a case where the temperature increase conditions were changed to the following condition B, were measured. The measurement results are shown in Table 1.
Condition A: Temperature increase from 20 to 250° C. at a temperature increase rate of 4° C./min
Condition B: Temperature increase from 20 to 250° C. at a temperature increase rate of 6° C./min

The temperature at which the prepreg A exhibited the minimum melt viscosity was 135° C. in the case of the condition A, and 145° C. in the case of the condition B.

TABLE 1

| Prepreg | | A | B | C | D | E | F | G | H |
|---|---|---|---|---|---|---|---|---|---|
| Polyimide resin 1 | | 50 | 50 | | | 50 | 50 | 50 | 50 |
| Polyimide resin 2 | | | | 50 | 50 | | | | |
| Epoxy resin | | 40 | 40 | 40 | 40 | 40 | 50 | 40 | 40 |
| (NC-3000-H) | | | | | | | | | |
| Curing | 2P4MHZ-PW | 0.5 | 0.5 | 0.5 | 0.5 | 0.5 | | 0.5 | 0.5 |
| accelerator | 2P4MZ | | | | | | 1.5 | | |
| Silica filler | | 40 | 40 | 40 | 40 | 40 | 50 | 40 | 40 |
| Resin content [wt. %] | | 50 | 70 | 50 | 70 | 35 | 50 | 40 | 80 |
| Minimum | Condition A | 4500 | 2500 | 2000 | 1500 | 5500 | 7000 | 5000 | 2000 |
| melt | Condition B | 3500 | | | | | | | |
| viscosity | | | | | | | | | |
| [Pa · s] | | | | | | | | | |
| Melt | Condition A | 60 | 110 | 120 | 150 | 50 | 40 | 55 | 125 |
| viscosity | Condition B | 80 | | | 160 | | | | |
| increase | | | | | | | | | |
| rate | | | | | | | | | |
| [kPa · s/min] | | | | | | | | | |

### 3. Production of Substrate Material

Any one of the prepregs A to H was cut into a square size that measured 250 mm on each side. Four sheets of the prepreg after cutting were stacked, and a copper foil (manufactured by MITSUI MINING & SMELTING CO., LTD., MT18EX-5) was disposed on both faces thereof. The laminated body of prepreg and copper foil was pressurized at a pressure of 3 MPa and a degree of vacuum of 40 hPa by using a heat pressing apparatus (manufactured by MEIKI CO., LTD., MHPC-VF-350-350-3-70), while sandwiching five sheets of a cushioning material (manufactured by Oji Paper Co., Ltd., KS190) having a thickness of 0.2 mm, which were arranged on both sides of the laminated body. While pressurizing, the temperature of the heat pressing apparatus was increased to the molding temperature of 230° C. by the following condition A or B, and then the laminated body was heated and pressurized for 2 hours while temperature was maintained at 230° C. Thereafter, end parts each having a width of 25 mm along the four sides of the laminated body were cut off by using cutting and sewing, to obtain a substrate material that included an insulating substrate and copper foils laminated on both faces thereof and had a square principal surface that measured 200 mm on each side. Table 2 shows the combinations of the prepreg and the temperature increase conditions applied to each Example or Comparative Example.
Condition A: Temperature increase from room temperature (about 25° C.) to 230° C. at a temperature increase rate of 4° C./min
Condition B: Temperature increase from room temperature (about 25° C.) to 230° C. at a temperature increase rate of 6° C./min

### 4. Evaluation of Substrate Material

Flatness (variations in thickness) of the substrate material, warpage, connectivity of solder bumps, fine wiring line formability, and variations in line width were evaluated by the following methods. The evaluation results are shown in Table 2. The minimum melt viscosity and the melt viscosity increase rate of the prepregs shown in Table 2 are values measured under temperature increase conditions corresponding to the temperature increase conditions employed for each Example or Comparative Example.

### Flatness (Variations in Thickness)

The principal surface of a substrate material was divided into sixteen square areas that measured 50 mm on each side, and the thickness at four sites at a position 2 mm inward from the four corners of each of the areas was measured by using a micrometer (manufactured by Mitutoyo Corporation, ID-C112X). The difference between the maximum value and the minimum value of thicknesses at the four sites measured in each of the sixteen areas was calculated, and the average value of the difference between the maximum value and the minimum value of thickness (average value of the difference in thickness) in the sixteen areas was calculated. The values of thickness at the four sites measured in each of the sixteen areas were used as a population, and the value of the standard deviation of thickness was calculated. The maximum value among the standard deviations of thickness in each of the sixteen areas was recorded as the standard deviation of the substrate material.

### Warpage

A substrate material was left to stand on a horizontal table, and the distances between the four sides of the substrate material measuring 200 mm on each side and the surface of the table were measured. The maximum value among the measured four distances was recorded as the value of warpage of the substrate material.

### Connectivity of Solder Bumps

A test substrate material having a square principal surface that measured 50 mm on each side was cut out from a substrate material by dicing. The substrate material was immersed in an aqueous solution of sulfuric acid having a concentration of 10% by mass for 1 minute. After washing with water, a fluxing agent (manufactured by SENJU METAL INDUSTRY CO., LTD., SPARKLE FLUX WF-6317) was applied on the surface of the substrate material. A semiconductor chip having solder bumps was placed on the surface of the substrate material where the fluxing agent was applied, and the semiconductor chip was mounted on the substrate material by heating in a nitrogen atmosphere in a reflow apparatus (manufactured by SENJU METAL INDUSTRY CO., LTD., SNR-1065GT) with the maximum temperature set at 260° C. The semiconductor chip used herein had copper pillars each having a diameter of 75 μm and a height of 45 μm and solder bumps (SnAg) having a height of 15 μm provided thereon, and had connection terminals arranged at a pitch of 150 μm. The semiconductor chip was obtained by dicing of a silicon wafer (manufactured by WALTS CO., LTD., FBW150-00SnAg01JY) having a thickness of 725 μm and had a square principal surface that measured 25 mm on each side.

The substrate material and the chip mounted thereon were cleaned by using an ultrasonic cleaning machine under the conditions of a frequency of 45 kHz and a cleaning time of 10 minutes to remove the fluxing agent, and then the substrate material and the chip were dried by heating at 100° C. for 30 minutes. Subsequently, an underfill was injected into the space between the substrate and the semiconductor chip on a hot plate heated to 110° C., and the substrate material and the semiconductor chip were further heated at 150° C. for 2 hours to obtain a semiconductor package for evaluation. A cross-section of each of the solder bumps located at the four corners of the semiconductor chip in the obtained semiconductor package was observed at 10 sites with a scanning electron microscope, and the connection between the solder bump and the copper foil of the substrate material was checked. A total of 120 sites were observed for three semiconductor packages produced by similar procedures. Among them, the proportion of places where connection between the solder bump and the copper foil of the substrate material was verified was calculated. A case in which this proportion was 90% or greater was determined as “A”, and a case in which this proportion was less than 90% was determined as “B”.

### Fine Wiring Line Formability

A test substrate material having a square principal surface that measured 50 mm on each side was cut out from a substrate material by dicing. Copper foil was removed from the substrate material by etching involving immersion in an aqueous solution of ammonium persulfate. A photosensitive insulating material (manufactured by Hitachi Chemical Company, Ltd., AR5100) was applied on the exposed insulating substrate using a slit coater, the coating film was dried by heating at 120° C. for 1 minute, and subsequently the coating film was cured by heating in a nitrogen atmosphere at 230° C. for 2 hours to form an insulating resin layer having a thickness of 5 μm. On the insulating resin layer, a titanium layer (thickness 50 nm) and a seed layer formed from a copper layer (thickness 150 nm) were formed by sputtering. A layer of a photoresist (manufactured by Hitachi Chemical Company, Ltd., RY-5107UT) was formed on the seed layer, and an area of the photoresist measuring 70 mm on each side was exposed to UV by using a projection exposure apparatus (manufactured by CERMA PRECISION, INC., S6Ck exposure machine). The photoresist after exposure was developed by spraying a 1% by mass aqueous solution of sodium carbonate by using a spin developing machine (manufactured by Blue Ocean Technology., Ltd., ultrahigh spin developing apparatus). By such exposure and development, 20 sets of a pattern in which 20 straight line portions having a length of 400 μm were lined up at the ratio of resist width/space width=2 μm/2 μm, were formed. The exposed surface of the seed layer was treated with oxygen plasma for 1 minute by using a plasma asher (manufactured by Nordson Advanced Technology (Japan) K.K., AP series batch plasma processing apparatus) under the conditions of an output power of 500 W, a pressure of 150 mTorr, and a gas volume of 100 sccm. Thereafter, copper plating having a thickness of 3 μm was formed on the seed layer by an electrolytic copper plating method. The photoresist was stripped off by using a 2.38% by mass aqueous solution of tetramethylammonium hydroxide. The exposed seed layer was washed at 23° C. for 30 seconds by using an aqueous solution prepared by mixing a copper etchant (manufactured by MITSUBISHI GAS CHEMICAL COMPANY, INC., WLC-C2) and pure water at a mass ratio of 1:1. Subsequently, the substrate material was immersed for 10 minutes in an aqueous solution at 23° C. prepared by mixing a titanium etchant (manufactured by MITSUBISHI GAS CHEMICAL COMPANY, INC., WLC-T) and a 23% aqueous ammonia solution at a mass ratio of 50:1 to remove the copper layer and the titanium layer. By the above-described operation, 20 sets of wiring lines formed from 20 straight line portions were formed. Among a total of 400 straight line portions of the formed wiring lines, the proportion of straight line portions that were recognized to have fallen was calculated. A case in which this proportion was 80% or greater and 100% or less was determined as “A”, a case in which this proportion was 50% or greater and less than 80% was determined as “B”, and a case in which this proportion was 0% or greater and less than 50% was determined as “C”.

### Variations in Line Width

Wiring lines were formed on a substrate material in the same manner as in the evaluation of the “Fine wiring line formability”, except that the ratio of resist width/space width was changed to 5 μm/5 μm. The width at any three sites of the wiring lines was measured by observing a cross-section of the wiring lines by using a scanning electron microscope (Hitachi High-Technologies Corporation, SUB200 type scanning electron microscope), and the standard deviation thereof was calculated.

TABLE 2

| | | 1 | 2 | 3 | 4 | 5 | 6 | 7 | 8 | 1 | 2 |
|---|---|---|---|---|---|---|---|---|---|---|---|
| Prepreg | | A | A | B | C | D | D | G | H | E | F |
| Prepreg resin | | 50 | 50 | 70 | 50 | 70 | 70 | 40 | 80 | 35 | 50 |
| content [wt %] | | | | | | | | | | | |
| Temperature | | A | B | A | A | A | B | A | A | A | A |
| increase condition | | | | | | | | | | | |
| Prepreg | | 4500 | 3500 | 2500 | 2000 | 1500 | | 5000 | 2000 | 5500 | 7000 |
| Minimum melt | | | | | | | | | | | |
| viscosity [Pa · s] | | | | | | | | | | | |
| Melt viscosity | | 60 | 80 | 110 | 120 | 150 | 160 | 55 | 125 | 50 | 40 |
| increase rate | | | | | | | | | | | |
| [kPa · s/min] | | | | | | | | | | | |
| Flatness | Average | 4 | 3 | 2 | 2 | 3 | 5 | 5 | 2 | 7 | 8 |
| [μm] | value of | | | | | | | | | | |
| | difference in | | | | | | | | | | |
| | thickness | | | | | | | | | | |
| | Standard | 3 | 2 | 1 | 1 | 2 | 4 | 4 | 1 | 5 | 7 |
| | deviation | | | | | | | | | | |

| | | | | | | | | | | |
|---|---|---|---|---|---|---|---|---|---|---|
| Warpage [μm] | 1.8 | 0.8 | 0.5 | 1 | 1.2 | 2.3 | 2.8 | 0.4 | 4.2 | 6.2 |
| Connectivity of | A | A | A | A | A | A | A | A | B | B |
| solder bumps | | | | | | | | | | |
| Fine wiring line | A | A | A | A | A | A | A | A | B | C |
| formability | | | | | | | | | | |
| Standard deviation | 0.8 | 0.4 | 0.2 | 0.3 | 0.4 | 0.9 | 1 | 0.2 | 1.4 | 2.1 |
| of line width [μm] | | | | | | | | | | |

As shown in Table 2, it was verified that by using a substrate material of each Example formed under the heating conditions in which the melt viscosity increase rate of the prepreg was 55×10³ Pa·s/min or greater, fine wiring lines could be stably formed while suppressing variations in the line width.

### REFERENCE SIGNS LIST

1: prepreg, 3: metal foil, 5: laminated body, 10: insulating substrate, 11: inorganic fiber base material, 12: thermosetting resin composition, 100: substrate material for semiconductor package.

1. A method for manufacturing a substrate material for a semiconductor package having an insulating substrate, the method comprising:
performing a molding treatment including increasing a temperature of a laminated body comprising two or more laminated sheets of a prepreg while pressurizing the laminated body, and thereby forming an insulating substrate from the prepreg,
wherein the prepreg comprises an inorganic fiber base material and a thermosetting resin composition impregnated into the inorganic fiber base material, a content of the thermosetting resin composition is 40% by mass or more and 80% by mass or less based on a mass of the prepreg, and
the molding treatment includes increasing the temperature of the laminated body under a heating condition in which a melt viscosity of the prepreg increases to 1000×10³ Pa·s at a rate of 55×10³ Pa·s/min or greater from a time point at which a minimum melt viscosity is exhibited.

2. The method according to claim 1, wherein the heating condition is a condition in which the melt viscosity of the prepreg increases to 1000×10³ Pa·s at a rate of 200×10³ Pa·s/min or less from the time point at which the minimum melt viscosity is exhibited.

3. The method according to claim 1, wherein the heating condition is a condition in which the prepreg exhibits a minimum melt viscosity of 10×10³ Pa·s or less.

4. The method according to claim 1, wherein the heating condition is a condition in which the prepreg exhibits a minimum melt viscosity of 5.0×10³ Pa·s or less.

5. The method according to claim 3, wherein the heating condition is a condition in which the prepreg exhibits a minimum melt viscosity of 1.0×10³ Pa·s or greater.

6. The method according to claim 1, wherein the method further comprises:
laminating one or more sheets of an additional prepreg on the formed insulating substrate to form a second laminated body; and
forming an insulating substrate after two times of lamination, the insulating substrate including a portion formed from the additional prepreg by a second molding treatment including increasing a temperature of the second laminated body while pressurizing the second laminated body,
the additional prepreg comprises an inorganic fiber base material and a thermosetting resin composition impregnated into the inorganic fiber base material, a content of the thermosetting resin composition is 40% by mass or more and 80% by mass or less based on a mass of the additional prepreg, and
the second molding treatment includes increasing the temperature of the second laminated body under a heating condition in which a melt viscosity of the additional prepreg increases to 1000×10³ Pa·s at a rate of 55×10³ Pa·s/min or greater from a time point at which a minimum melt viscosity is exhibited.

7. A prepreg comprising an inorganic fiber base material and a thermosetting resin composition impregnated into the inorganic fiber base material,
wherein a content of the thermosetting resin composition is 40 to 80% by mass based on a mass of the prepreg, and
a melt viscosity of the prepreg measured at a temperature increase rate of 4° C./min increases to 1000×10³ Pa·s at a rate of 55×10³ Pa·s/min or greater from a time point at which a minimum melt viscosity is exhibited.

8.-9. (canceled)
